(19) United States
(12) Patent Application Publication
(10) Pub. No.: US 2010/0247790 A1
(43) Pub. Date: Sep. 30, 2010

(54) INTERACTIVE ENAMELLED VISUAL COMMUNICATION PANEL

(75) Inventor: Leo Albert Julia Gypen, Zonhoven (BE)

Correspondence Address: DOWELL & DOWELL P.C., 103 Oronoco St., Suite 220, Alexandria, VA, 22314, US

(73) Assignee: POLYVISION, NAAMLOZE VENNOOTSCHAP, Genk (BE)

(21) Appl. No.: 12/666,788

(22) PCT Filed: Jun. 25, 2008
(86) PCT No.: PCT/BE2008/000046

§ 371 Date: May 11, 2010

(30) Foreign Application Priority Data
Jun. 27, 2007 (BE) 2007/0319

(51) Int. Cl. B05D 3/02; G03F 7/20; B41M 1/12; G06F 3/041

(52) U.S. Cl. 427/397.7; 430/320; 101/129; 345/173

(57) ABSTRACT

Interactive visual communication panel (1), such as among others a board that can be written on with felt-tip pens or a chalkboard that can be written on with chalk, characterised in that it is provided with an vitreous enamel layer (5) on the front (3) of the communication panel (1) on which is provided an optically readable position-encoding pattern (6) for creating an electronic representation of the information that is written on the front (3), which position-encoding pattern (6) is built of a ceramic print that has been fired on the layer of enamel (5) at temperatures higher than 500° C.

The present invention concerns an interactive vitreous (porcelain) enamelled visual communication panel, i.e. a board that can be written on for example with dry-erasable felt-tip pens and that can be erased or a chalkboard to write on with chalk or the like.

Interactive communication panels are capable of digitally storing the data that are written on the communication panel for example during a presentation, and possibly they may simultaneously project these data and provide other interactions between the communication panel, a computer and several peripherals.

Known interactive communication panels use the well-known “touch-screen” technology, whereby a flexible screen is put in front of a pressure-sensitive panel, such that while the flexible screen is being written on, the data concerned are registered.

The pressure-sensitive panel usually consists of a grid of crossed conductors which make contact when a point in the pressure-sensitive panel is being pressed on.

A problem that arises in this case is that the flexible screen is not easy to erase. Furthermore, such screens show poor mechanical properties such as scratch and wear resistance.

Vitreous (porcelain) enamelled communication panels cannot be used as flexible screens, due to the high rigidity of the steel plate which are is coated with one or several layers of vitreous enamel.

Another known type of interactive communication panels provides a surface with an optically readable position-encoding pattern for creating an electronic display of the information that is written on the surface.

A first major advantage is that such an interactive communication panel may have an extremely simple construction and does not need to comprise any electronic components as such to be able to form an electronic representation of the information that is written on the surface.

Combined with a reading instrument that is capable of forming an electronic representation of the information that is written on the communication panel, an interactive communication panel is thus obtained.

Such a reading instrument may for example consist of a writing means, such as a dry-erasable felt-tip pen or a piece of chalk, provided with optical reading means and with means that permanently follow the changes in position of the writing means. A second major advantage consists in that such interactive communication panels, provided with an optically readable position-encoding pattern, register what is written on the board with significantly more accuracy than pressure-sensitive interactive boards.

Such an interactive communication panel and the accompanying reading instruments are described in detail in WO 01/16872, whose content is incorporated in the present document by means of references.

A problem that arises now is that the intended writing surfaces cannot be erased well which, after a while, compromises the readability of the optically readable position-encoding pattern.

In order to obtain a durable and economical interactive communication panel, the present invention concerns an interactive visual communication panel provided with a layer of vitreous enamel on the writing side of the communication panel on which is printed an optically readable position-encoding pattern so as to create an electronic representation of the information that is written on the writing side.

Such a communication panel offers all the advantages of a communication panel as described in WO 01/16872, and it additionally guarantees the long-lasting readability of the position-encoding pattern.

Indeed, thanks to their high scratch resistance and wear resistance, such ceramic boards retain good erasing characteristics, even after many cycles of use.

According to a preferred embodiment, the above-mentioned pattern is provided by means of a silkscreen printing technique that uses a very fine sieve, for example a sieve of 140 T or even finer, what comes down to a sieve having at least 140 meshes per stretching centimetre, and whose wire gauge amount to less than 35 μm, for example 31 μm.

Such sieves make it possible to apply an vitreous enamelled pattern, for example a dot pattern as mentioned in WO 01/16872 and as described in detail in Swedish patent application No. 9903541-2, on for example a steel plate.

Such a steel plate has been provided beforehand with for example a predominantly uniform layer of vitreous enamel, for example a white or green layer of vitreous enamel, fired at a temperature of more than 500° C., for example at 820° C.

The above-mentioned 140 T sieve with fine wires is provided with a photo-sensitive substance that is subsequently exposed in correspondence with the aimed pattern. Next, the sieve is put in front of the enamel plate to be printed on, and an enamel mixture is provided through the openings that is fired later on at a temperature that is somewhat lower than the temperature at which the first layer or layers had been burnt in, but that is always higher than 500° C., for example 740° C.

According to a particularly preferred embodiment, the above-mentioned pattern is provided by means of a direct photographic process.

This technique is advantageous in that a pattern can be provided with even more accuracy than with the silkscreen printing technique.

A photosensitive emulsion is hereby provided on the enamelled steel plate, possibly by means of a sieve. As soon as it has dried, the film is put against the plate with the photosensitive emulsion printed on it, and only then the enamelled plate with the emulsion and the film is exposed, in correspondence with the aimed representation.

Next, the film is removed and the non-exposed and thus non-bonded emulsion is removed.

The emulsion is formed of polymers in which have been provided vitreous enamel particles and pigment. There where the emulsion is exposed, the polymers bond and the emulsion adheres to the enamel plate.

After removal of the non-bonded emulsion, the remaining vitreous enamel, i.e. the enamel particles and the pigment, are fired at a temperature that is lower than the temperature at which the first layer or layers had been burnt in, but always at more than 500° C., for example at 740° C.

The advantage that is obtained by applying the direct photographic process is the high accuracy or the high resolution of the print, which is required for reading the position-encoding pattern.

According to a special embodiment of the invention, the pattern may also be provided by means of what is called the toner jet technique.

This regards the printing of a ceramic dot pattern by means of a printing technique that is analogous to the known photocopy technique, after which the obtained pattern is fired at more than 500° C. The particle size of the ceramic toner hereby amounts to only a few μm.

According to another embodiment of the invention, the pattern can also be provided by means of what is called laser-perforated foil printing.

The ceramic dot pattern is printed by applying a foil on the surface of the enamelled steel. This foil has been perforated beforehand by means of a laser, in correspondence with the dot pattern. Then, a ceramic paste is provided on the enamelled steel via rake printing, after which the foil is removed and the obtained pattern is fired at over 500° C.

According to another preferred embodiment of the invention, the pattern can also be provided by means of transfer printing.

The ceramic dot pattern is first provided on a foil, after which it is transferred for example by heat from the foil to the surface of the vitreous enamelled plate. Next, the obtained pattern is fired at over 500° C.

Another embodiment of the invention is related to applying the pattern by means of what is called “laser marking” with the addition of enamel.

A uniform layer of enamel and pigment is hereby provided on the enamelled plate. Then, the dot pattern is melted on the enamelled steel by locally melting enamel and pigment.

As an alternative, use can be made of laser marking without any enamel being added.

The dot pattern is hereby burnt directly in the enamelled plate by means of a laser by locally melting the white enamel topcoat, as a result of which it becomes transparent, which results in black dots due to the base enamel becoming visible.

The ceramic paste that is used for printing the position-encoding pattern may be composed as follows, for example:

1) 30 to 70 parts by weight uncoloured organic silkscreen printing media for printing. These media evaporate entirely while the paste is being fired;

2) 20 to 60 parts by weight boro-silicate glass having the following composition: 19.9% sodium; 0.9% aluminium; 32.8% silicon; 1.51% sulphur; 16.0% potassium; 5.7% barium; 22.2% titanium; 0.9% copper;

3) 5 to 20 parts by weight ceramic colorant having the following composition: 1.1% aluminium; 8.4% silicon; 0.6% sulphur; 30.9% chromium; 4.3% manganese; 28.2% iron; 26.5% copper.

Given the high gloss of enamelled panels compared to that of paper or other traditional materials that are used for communication panels, the present invention also aims to reduce the gloss.

To that end, the present invention also concerns an interactive communication panel which mainly consists of a support, for example a steel plate, onto which is provided an vitreous enamel layer, whereby on the visible side of the layer of enamel, where a position-encoding pattern is provided as well, a sol gel dispersion is provided that is subsequently tempered so as to form a predominantly glassy or ceramic cover layer.

The method for manufacturing such a communication panel with a sol gel dispersion is described in detail in EP 1,016,588, whose content is incorporated in the present patent application by this reference to it.

This cover layer is formed by applying what is called a sol gel dispersion on the layer of vitreous enamel and by subsequently tempering the dispersion at a temperature ranging between 200° and 600° C. and which preferably amounts to some 510° C.

The above-mentioned sol gel dispersion is defined here as a usually colloidal solution of inorganic metal salts and/or organic metal compounds such as metal alkoxides, whereby this solution or, in particular, this liquid dispersion is transformed in what is called a ‘sol’ condition during a drying process and forms the above-mentioned cover layer after having been tempered.

The sol gel dispersion is hereby preferably prepared from a base solution of metal alkoxides to which a preferably watery colloidal silica solution and/or particles of metal oxide or the like are added.

Preferably, the reduction of specular gloss by sol gel coating can be obtained in two ways. One is to increase the diffuse reflection of incident light, thus inherently decreasing the specular reflection. This is the principle of an Anti Glare (AG) sol gel coating. The second way is to apply a sol gel coating which decreases the specular reflection itself, which is called an Anti Reflection sol gel coating. The principle of an Anti Reflection sol gel coating is described “in detail below”.

The thickness of the sol gel layer is such that it corresponds to a quarter of the wavelength of the visible light or of the light that is used for reading the pattern, what comes down to a layer thickness for the sol gel of 75 to 180 nanometres, and such that light which is reflected by the surface which forms the transition between the ambient air and the sol gel layer is at least partly neutralised by light that is reflected by the surface which forms the transition between the sol gel layer and the underlying layer of vitreous enamel.

Indeed, if the sol gel layer has a thickness of a quarter of a wavelength of the light whose reflection one aims to reduce, and the sol gel layer has a refractive index that is smaller than that of the underlying layer, in this case a layer of vitreous enamel, then the two reflected waves will have a phase difference of 180°, at least the waves that are perpendicularly incident on the surface. The light waves that are incident at an aberrant angle of incidence are not neutralised, but they are strongly suppressed. Mathematically, this is expressed as

n·d=λ/4

Whereby n is the refractive index of the sol gel layer, d is the thickness of the layer and λ is the wavelength of the light. The product of n and d is called the optical thickness of the layer.

Such an anti-reflection finish that is formed of a single layer is only optimal for a single wavelength. Usually, the thickness of the layer is adapted to the centre of the visible spectrum, what comes down to some 550 nm. This wavelength is called the ‘design wavelength’. Consequently, such a layer will have a minimal reflection in the centre of the visible spectrum.

The size of this minimum depends on the size of the refractive index of the sol gel layer. The optimum is calculated as

n=(n₀nₛ)^{1/2}

whereby n₀ stands for the refractive index of the surrounding medium (usually air n₀=1) and whereby nₛ is the refractive index of the substrate. In most applications, the substrate is enamel or a polymer material having a refractive index of ₛ close to 1.5.

In this case, the ideal refractive index of the sol gel layer would amount to 1.22.

A single transparent sol gel layer as described in EP 1,016,588 with a layer thickness that is equal to one quarter of the wavelength of visible light results in an anti-reflective layer with a sol gel layer thickness between 75 and 180 nanometres.

The availability of materials having such a low refractive index restricts the effectiveness of an antireflective finish formed of a single layer. The materials that are most used are MgF₂ having a refractive index of 1.38, and also the nano-porous SiO₂ is often used.

If the substrate is a white vitreous enamelled enamel, the white colour is obtained thanks to the precipitation of TiO₂. The qualities of enamel are quite similar to those of borosilicate glass, but with the presence of TiO₂ (having a reflection index of 2.4), the reflection index of the vitreous enamel substrate is estimated at 1.6 to 1.7, as is confirmed by ellipsometric measurements.

An anti-reflection finish can be made much more effective by providing two or several layers. An anti-reflection finish with two layers whose thickness equals one quarter of the wavelength of the light whose reflection one aims to reduce, has a simple construction.

The construction of an anti-reflection finish with more than two layers becomes more complex, however, and its design requires complicated calculations. In this case, layers are sometimes provided for example, whose thickness corresponds to half a wavelength of the light whose reflection one aims to reduce.

The present invention also concerns some specific aspects regarding the reading instrument that is capable of forming an electronic representation of the information that is written on the communication panel.

These specific aspects solve the problems caused by the higher gloss of enamelled panels.

A reading instrument that is capable of forming an electronic representation of the information that is written on the communication panel is preferably connected to the pen and is preferably provided with a light-sensitive detector that is designed to detect a position-encoding pattern on a writing panel so as to determine the current position of the pen, and further the reading instrument preferably comprises communication means that are fit for transmitting information regarding the position of the pen based on the position-encoding pattern as established by the above-mentioned detector to at least one external unit.

By means of the light-sensitive detector and the above-mentioned communication means on the one hand, and the position-encoding pattern on the writing panel on the other hand, the position changes of the felt-tip pen, pen or piece of chalk are permanently followed.

The reading instrument preferably also comprises a light source, for example a LED, to illuminate the surface of the communication panel, in particular to promote the readability of the pattern provided on it.

The light source may emit visible light or invisible, infrared light.

The ceramic paste used for the dot pattern may be such according to an aspect of the present invention that it absorbs the light of the light source of the reading instrument, such that the optical detection of the pattern is improved.

More specifically, the used ceramic paste can be such that it absorbs the infrared light of 800-950 nm.

In order to solve the reading problems caused by the often high gloss of enamel panels, the detector is preferably oriented such in relation to the above-mentioned light source, and possibly positioned at a distance thereof, that it mainly registers light outside the angle of reflection of the incident light beam.

The reading instrument that is connected to the pen, the felt-tip pen or the piece of chalk or the like, or the pen itself, can be made such that, when it is manipulated by a user, it is mainly held in a certain preferred direction in relation to the writing panel.

Such an embodiment can for example be obtained by providing a grip zone with such a design that it can only be held in mainly one particular way, in particular such that the above-mentioned aim is obtained.

In order to better explain the characteristics of the invention, the following preferred embodiment of an interactive enamelled visual communication panel according to the invention is described as an example only without being limitative in any way, with reference to the accompanying drawings, in which:

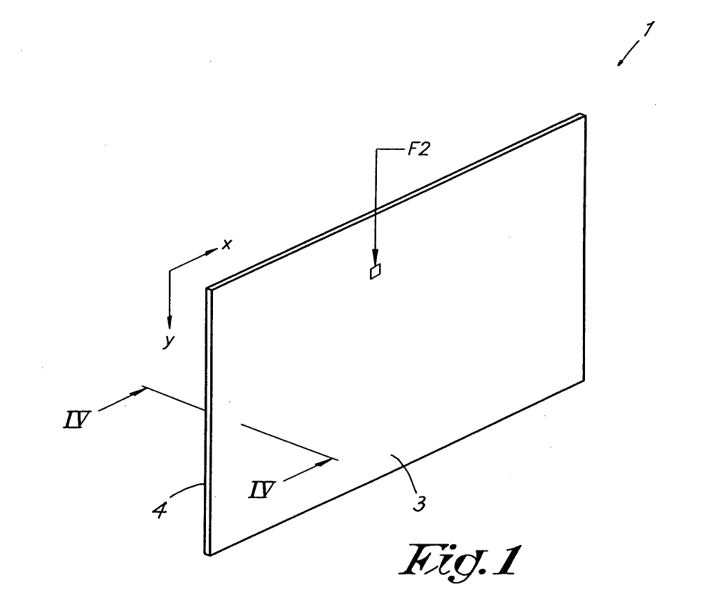

FIG. 1 schematically represents a visual communication panel according to the invention;

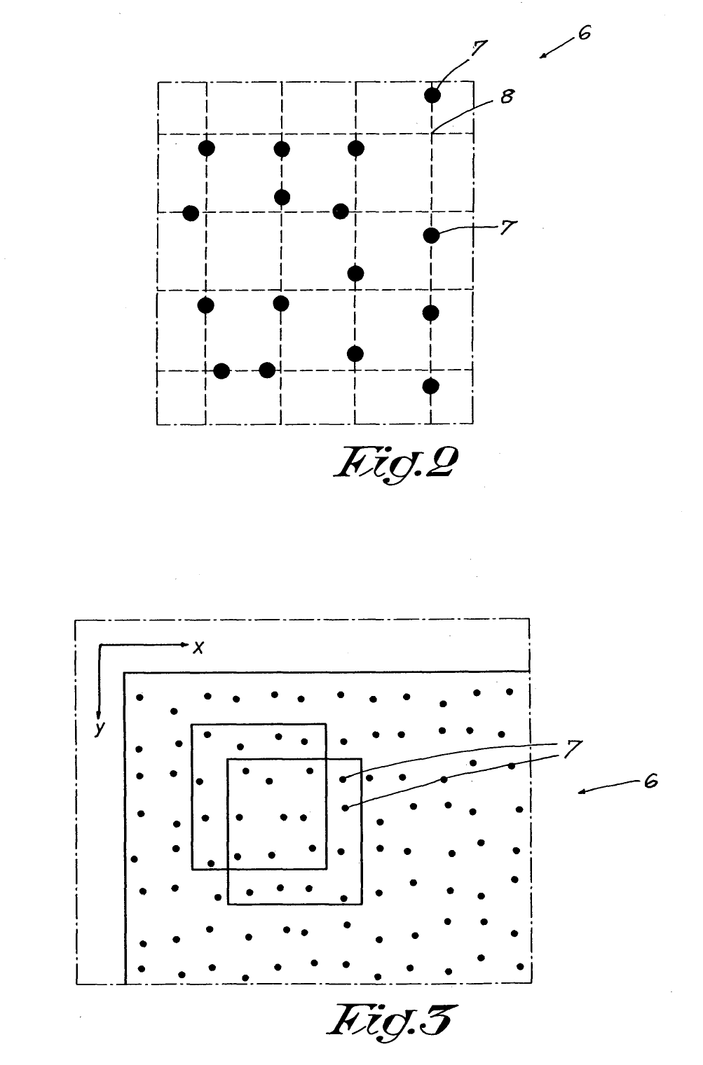

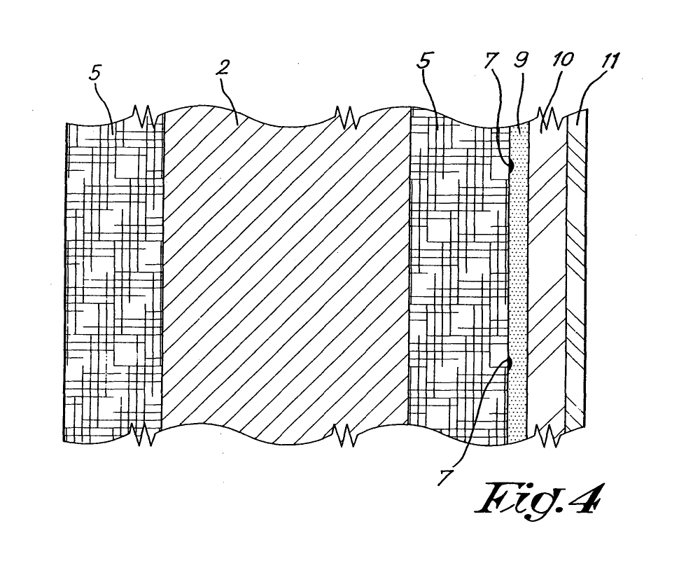

FIGS. 2 and 3 represent the position-encoding pattern in detail;

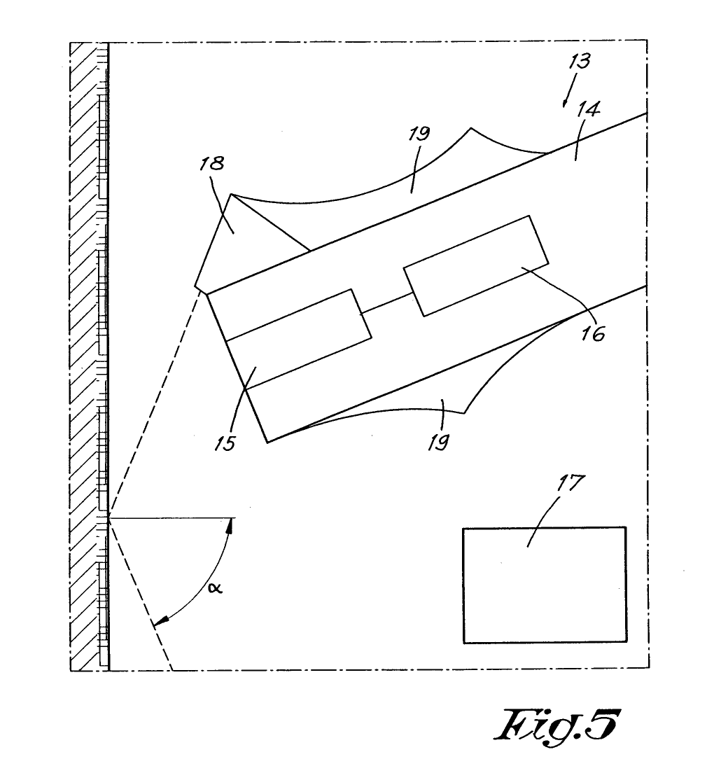

FIG. 4 represents a section according to line IV-IV in FIG. 1 to a larger scale;

FIG. 5 represents the communication panel according to FIG. 1, together with a reading instrument according to the invention.

The visual communication panel 1 as represented in FIG. 1 mainly consists of a steel plate 2 having a thickness of 0.35 mm in this case, provided with a predominantly white layer of vitreous enamel 5 of 0.10 mm thick on the front 3 in this case.

The front 3 or the writing side of the communication panel 1 is additionally provided with a readable position-encoding pattern 6.

The position-encoding pattern 6 is formed of small black dots 7 in this case that can actually be provided over mainly the entire surface of the front 3 of the communication panel 1, and that are smaller than represented in the figures, such that a sufficiently large resolution is obtained.

The position-encoding pattern 6 can be created in different ways. The position-encoding pattern 6 as represented corresponds to the pattern as described in WO 01/16872. The description concerned is incorporated in the present patent application by referring to it.

In short, and as represented in FIG. 2, it comes down to it that a virtual grid, represented by means of a dotted line here but not visible in reality, is provided on the writing surface 3 of the communication panel 1, and near every virtual node 8 of the grid is provided a dot 7, shifted somewhat to the top however, to the left, to the right or to the bottom in relation to the virtual node 8.

The distance between the nodes 8 amounts to 0.3 mm here, the diameter of the dots 7 is 100 μm, and the shift in relation to the virtual node amounts to 50 μm.

Depending on the size of the communication panel 1 and the desired resolution of the positioning, four by four, i.e. sixteen dots 7, or six by six, i.e. thirty six dots 7 may suffice, for example, to identify the position.

FIG. 3 shows a position-encoding pattern 6 by way of example, in which the registration of the shifts of four by four dots 7 in relation to the respective virtual nodes 8 suffices to identify each position.

FIG. 4 represents the communication panel 1 to a larger scale, seen as a section. The steel plate 2 is represented here which is provided with a predominantly white layer of vitreous enamel 5 on the front 3 4.

On top of the layer of vitreous enamel 5 and the encoding pattern 6 with dots 7 provided on it are provided three sol gel layers 9 to 11, having a thickness λ/4, λ/2, λ/4 respectively.

FIG. 5 represents a reading instrument 13 which is capable of forming an electronic representation of the information that is written on the communication panel 1, having an integrated writing means 14 in this case, in particular a felt-tip pen 14 that is designed to write on a white vitreous enamelled communication panel 1.

The reading instrument 13 comprises a light-sensitive detector 15 that is designed to detect a position-encoding pattern 6 on a writing panel 1 so as to determine the current position of the felt-tip pen, and further the reading instrument 13 comprises communication means 16 that are fit for transmitting information regarding the position of the felt-tip pen 14 based on the position-encoding pattern 6 as detected by the above-mentioned detector 15 to at least one external unit 17.

By means of the light-sensitive detector 15 and the above-mentioned communication means 16 on the one hand, and the position-encoding pattern 6 on the communication panel 1 on the other hand, the position changes of the writing means 14 are permanently followed.

The reading instrument preferably also comprises a light source 18, for example a LED, to illuminate the surface of the communication panel 1, in particular to promote the readability of the position-encoding pattern 6 that is provided on it.

In order to solve the reading problems caused by the often high gloss on enamel panels, the detector 15 is oriented such in relation to the above-mentioned light source 18, and positioned at a distance thereof, that the detector 15 mainly registers light situated outside the angle of reflection α of the incident light beam.

The reading instrument 13 with its integrated writing means 14 is provided with a grip zone 19 which encourages the user to hold the writing means 14 in a preferred direction, in particular such that the detector 15 mainly registers light situated outside the angle of reflection α of the incident light beam.

A method for manufacturing a visual communication panel according to the invention consists in providing a steel plate 2 with a layer of vitreous enamel 5 at least on the front 3 and in firing it at for example 820° C.

This can take place for example in a continuous process whereby the thus obtained vitreous enamelled plate may be recoiled so as to be processed later, or it is immediately cut in sheets that form the base of a communication panel 1.

The above-mentioned position-encoding pattern 6 is provided by means of a direct photographic process.

This process consists in providing a photo-sensitive emulsion on the vitreous enamelled steel plate, possibly by means of a sieve. After it has dried, the film is put against the plate that has the photo-sensitive emulsion printed on it, and only then the layer of enamel 5 is exposed together with the emulsion and the film, in correspondence with the aimed representation.

Next, the film is removed, and the non-exposed and thus non-bonded emulsion is removed.

Indeed, the emulsion consists of polymers in which have been provided vitreous enamel particles and pigment. There where the emulsion is exposed, the polymers are bonded and the emulsion adheres to the vitreous enamel plate.

After the non-bonded emulsion has been removed, the enamel that is left, i.e. the enamel particles and the pigment, is fired at a temperature that is lower than the temperature at which the first layer or layers had been burnt in, for example at 740° C.

This technique is advantageous in that a position-encoding pattern 6 can be provided with high accuracy and thus with a higher resolution compared to the silkscreen printing technique.

Next, the three layers of sol gel 9 to 11 are successively provided so as to reduce any reading problems caused by the high gloss.

A layer of sol gel dispersion that has been provided is subsequently tempered so as to form a mainly glassy or ceramic cover layer.

The dispersion can be tempered at a temperature situated between 200° and 600° C., and which preferably amounts to some 510° C.

The above-mentioned layers of sol gel dispersion 9 to 11 in this case consist of a colloidal solution of inorganic metal salts and organic metal components, such as metal alkoxides, whereby this solution or, in particular, this liquid dispersion is transformed in what is called a ‘sol’ condition during a drying process and forms the above-mentioned cover layer after having been tempered.

The sol gel dispersion is in this case prepared from a base solution of metal alkoxides to which a watery colloidal silica solution and/or particles of metal oxide or the like are added.

The layer 9 that is provided on the enamel in this case consists of CeF₃ and has a refractive index n=1.65, but it may for example also be formed of Al₂O₃ with a refractive index n=1.76.

The middle layer 10 is in this case formed of ZrO₂ and has a refractive index n=2.10.

The outer layer 11 is in this case formed of MgF₂ and has a refractive index n=1.38.

It is clear that the different described methods according to the invention for applying a position-encoding pattern 6, as well as for providing one or several sol gel layers 9-11 according to the invention, as well as the use of the reading instrument according to the invention can be applied or can be used independently from one another, and that the selection of one of these elements does not require the presence or application of the other elements.

If a reading instrument 13 with a light source 18 is used in combination with one or several layers of sol gel, then the thicknesses or the cumulated thicknesses of these layers can be adjusted to the frequency of the light emitted by the light source 18.

It is clear that the position-encoding pattern, generally represented as dark dots in what precedes, may also be formed of light-absorbing or especially reflecting dots. Such an embodiment can be particularly useful in the case of dark chalkboards that can be written on with chalk or the like, and/or when the light source 18 emits an infra-red light.

It is clear that, if the communication panel 1 concerns a chalkboard, the writing means 14 may be a piece of chalk 14 to write on said blackboard with.

The present invention is by no means restricted to the embodiment described as an example and represented in the accompanying drawings; on the contrary, such an interactive communication panel can be made while still remaining within the scope of the invention.

1. Interactive visual communication panel (1), such as among others a board that can be written on with felt-tip pens or a chalkboard that can be written on with chalk, characterised in that it is provided with an vitreous enamel layer (5) on the front (3) of the communication panel (1) on which is provided an optically readable position-encoding pattern (6) for creating an electronic representation of the information that is written on the front (3), which position-encoding pattern (6) is built of a ceramic print that has been fired on the layer of vitreous enamel (5) at temperatures higher than 500° C.

2. Interactive visual communication panel according to claim 1, characterised in that the position-encoding pattern (6) is provided by means of a silkscreen printing technique that makes use of a very fine sieve, for example a sieve of 140 T or even finer, and of which the wire gauge is less than 35 μm.

3. Interactive visual communication panel according to claim 1, characterised in that the position-encoding pattern (6) is provided by means of a direct photographic process.

4. Interactive visual communication panel according to claim 1, characterised in that on the layer of enamel (5) on which is provided a position-encoding pattern (6), is provided a sol gel dispersion that is subsequently tempered so as to form a predominantly glassy or ceramic cover layer (9-11).

5. Interactive visual communication panel according to claim 4, characterised in that the thickness of the sol gel layer (9-11) is such that it corresponds to a quarter of the wavelength of the visible light, what comes down to a layer thickness for the sol gel layer (9-11) of 75 to 180 nanometres.

6. Interactive visual communication panel according to claim 4, characterised in that several sol gel layers (9-11) are provided, whereby the layer thicknesses and compositions of the different sol gel layers (9-11) are selected such that anti-reflective qualities are obtained.

7. Interactive visual communication panel according to claim 6, characterised in that the different sol gel layers (9-11) have different compositions.

8. Method for manufacturing an interactive visual communication panel (1) as described in claim 1, characterised in that the position-encoding pattern (6) is provided by means of a silkscreen printing technique which makes use of a very fine sieve, for example a sieve of 140 T or even finer, and whose wire gauge amounts to less than 35 μm.

9. Method for manufacturing an interactive visual communication panel (1) as described in claim 1, characterised in that the position encoding pattern (6) is provided by means of a direct photographic process.

10. Method for manufacturing an interactive visual communication panel (1) as described in claim 1, characterised in that on the layer of vitreous enamel (5) on which is provided a position-encoding pattern (6) is provided a sol gel dispersion that is subsequently tempered so as to form a predominantly glassy or ceramic cover layer.

11. Reading instrument (13) which is capable of forming an electronic representation of the information that is written on the communication panel, connected to or integrated with the writing means (14), which is for example a felt-tip pen when it is meant to be used in combination with a board that can be written on with dry-erasable felt-tip pens and that can be erased, or for example a piece of chalk when it is designed to be used in combination with a dark chalkboard or the like that can be written on with chalk, and whereby the reading instrument is provided with a light-sensitive detector (15) which is designed to detect a position-encoding pattern (6) on a communication panel (1) so as to determine the current position of the writing means (14), and the reading instrument (13) is further provided with communication means (16) that are fit to transmit information regarding the position of the writing means (14) based on the position-encoding pattern (6) as was established by the above-mentioned detector (15) to at least one external unit (17), characterised in that the reading instrument (13) is provided with a light source (18), for example a LED, to illuminate the front (3) of the communication panel (1), in particular to improve the readability of the pattern (6) that is provided on it, whereby the light-sensitive detector (15) is oriented such in relation to the above-mentioned light source (18) and is possibly positioned at a distance thereof, that it mainly registers light outside the angle of reflection (α) of the incident light beam.

12. Reading instrument according to claim 11, characterised in that it is made such that, when it is manipulated by a user, it is predominantly held according to one or several possible preferred orientations in relation to the communication panel (1) or within a certain margin thereof.

13. Reading instrument according to claim 12, characterised in that the reading instrument (13) is provided with a grip zone (19) having such a design that it can only be held in mainly one way or in a restricted number of ways, in particular such that this results in the above-mentioned preferred orientations.
